(19) United States
(12) Patent Application Publication
(10) Pub. No.: US 2008/0157322 A1
(43) Pub. Date: Jul. 3, 2008

(54) Double side stacked die package

(76) Inventors: Jia Miao Tang, Shanghai (CN); Xiang Yin Zeng, Shanghai (CN); Daoqiang Lu, Chandler, AZ (US); Jiangqi He, Gilbert, AZ (US)

Correspondence Address: INTEL/BLAKELY, 1279 OAKMEAD PARKWAY, SUNNYVALE, CA, 94085-4040, US

(21) Appl. No.: 11/647,086

(22) Filed: Dec. 27, 2006

(51) Int. Cl. H01L 23/02; H01L 21/00

(52) U.S. Cl. 257/686; 438/119; 257/E23.18; 257/E21.001

(57) ABSTRACT

A method of forming a package, comprising providing a set of dies on a substrate. The substrate may have a first die on its upper side and a second die on its lower side. A first interconnect may be provided in the substrate, wherein the first interconnect penetrates through the substrate to couple the dies to the substrate.

### BACKGROUND

Some stacked die packages may utilize wire bonds in the packages. However, the golden wire process may increase electrical response time. Further, the package size and the thickness may be increased due to wire bonding and molding processes. Using golden wire and molding compound material may increase the total cost and wire bond shorting may happen after molding. Also, warpage may happen due to an unbalanced architecture of the present stacked die packages. There would be requirement of under fill epoxy to protect the bump joint for a substrate and a die in some process since there is a significant coefficient of thermal expansion mismatch.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 is a schematic diagram of an embodiment of a semiconductor package,

FIG. 2A to 2F are schematic diagrams of an embodiment of a method that may provide the semiconductor package of FIG. 1,

FIG. 3 is a schematic diagram of an embodiment of a memory system.

### DETAILED DESCRIPTION

In the following detailed description, references is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, and other similar references, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The following description may include terms, such as upper, lower, top, bottom, first, second, etc. that are used for descriptive purposes only and are not to be construed as limiting.

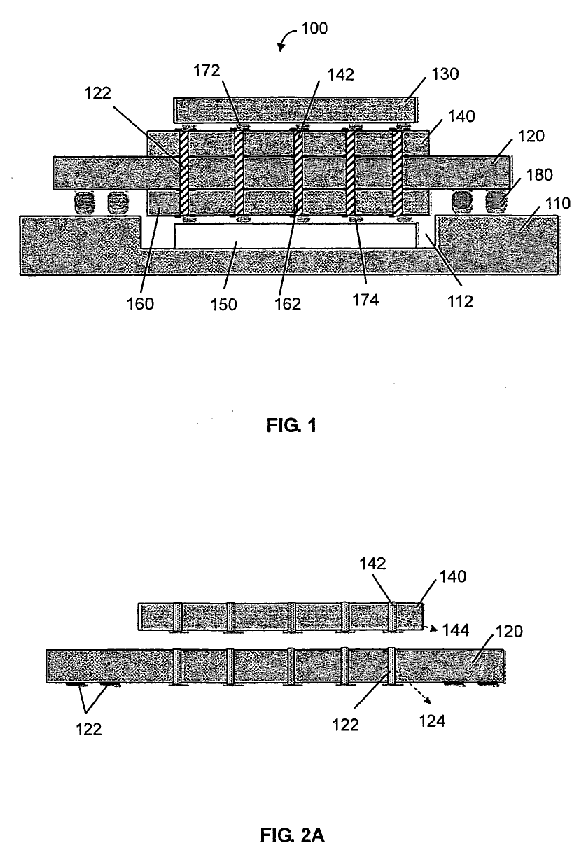

FIG. 1 illustrates an embodiment of a semiconductor package 100. In one embodiment, the package 100 may be supported on a mother board 110. In another embodiment, the package 100 may be coupled to the mother board 110. Referring to FIG. 1, the semiconductor package 100 may comprise a substrate 120. Any suitable substrate may be utilized, including flex substrates such as folded flex substrates or flexible polyimide tape, laminate substrates such as bismaleimide triazine (BT) substrates, buildup substrates, or ceramic substrates. In one embodiment, the substrate 120 may comprise a set of dies on each side. Each set of dies may comprise one or more dies. For example, referring to FIG. 1, the substrate 120 may comprise a first die 130 and a second die 140 stacked on its upper side. The substrate 120 may further comprise a third die 150 and a fourth die 160 on its lower side. In one embodiment, die attach adhesive (not shown), such as epoxy, paste or adhesive tape, may be used to secure stacked dies 140 and 160 to the substrate 120. In other embodiments, die attach adhesives may not be required.

The substrate 120 may comprise a set of one or more plated through holes (PTH) 122 that may reach or extend to both sides of the substrate 120 to couple the substrate 120 to the second die 140 and the fourth die 160. In one embodiment, the second die 140 may comprise a set of plated through vias 142 that may each be coupled to a PTH 122. In one embodiment, example of the plated through vias 142 may comprise a through silicon via (TSV). Similarly, the PTHs 122 in the substrate 120 may each be coupled to a plated through via 162 in the fourth die 160. While the embodiment of FIG. 1 utilizes PTHs and/or plated through vias to couple the substrate 120 and the dies 140 and 160, in some embodiments, other interconnects may be applied, such as conductive or metal layers, bond pads, bumps, conductive paste. In another embodiment, the dies may be coupled to the substrate 120 by interconnects that penetrate through the substrate 120 and/or the dies.

Referring to FIG. 1, the first die 130 may be coupled to the second dies 130 by a set of one or more bumps 172; however, in some embodiments, other interconnects may be utilized, such as solder balls, conductive protrusions, metal layers, leads. For example, the bumps 172 may each be coupled with a plated through via 142. In another embodiment, the first die 130 may be implemented as a bump die that may be configured with the bumps 172 on one side. Similarly, a set of bumps 174 may be used to couple the third die 150 to the fourth die 160. In one embodiment, the third die 150 may be implemented as a bump die that may be configured with the bumps 174.

As shown in FIG. 1, the semiconductor package 100 may be disposed on a mother board 110. In one embodiment, the substrate 120 may be coupled to the mother board 110 by interconnects such as solder balls 180. While FIG. 1 is described with a ball grid array or solder balls, in some embodiments, other external interconnects may be utilized. For example, land grid arrays may also be utilized. In another embodiment, the substrate 120 may be wire bonded to the mother board 110. In one embodiment, the mother board 110 may comprise an opening 112 that may accommodate the semiconductor package 100 of the first substrate 120 and the dies 130, 140, 150 and 160. For example, the lower die 160 may be located on a bottom surface of the opening 112.

While FIG. 1 shows four dies attached to the substrate 120, in some embodiments, a different number of dies may be utilized. For example, the substrate 120 may comprise three dies on an upper side, wherein two lower dies may be coupled to the substrate 120 by PTHs and/or plated through vias and an upper die may be coupled to the substrate 120 by bumps. In another embodiment, examples of the package 100 may comprise flash memory, static random access memory (SDRAM), digital signal processor (DSP), application specific integrated circuit (ASIC), logic circuits, CPU, system level components, or any other circuits or devices. In another embodiment, a back side of the die 140 or 160 may face to substrate. In another embodiment, the dies may be coupled by bumps or any suitable joints. The dies on both sides of the substrate may provide a balanced package.

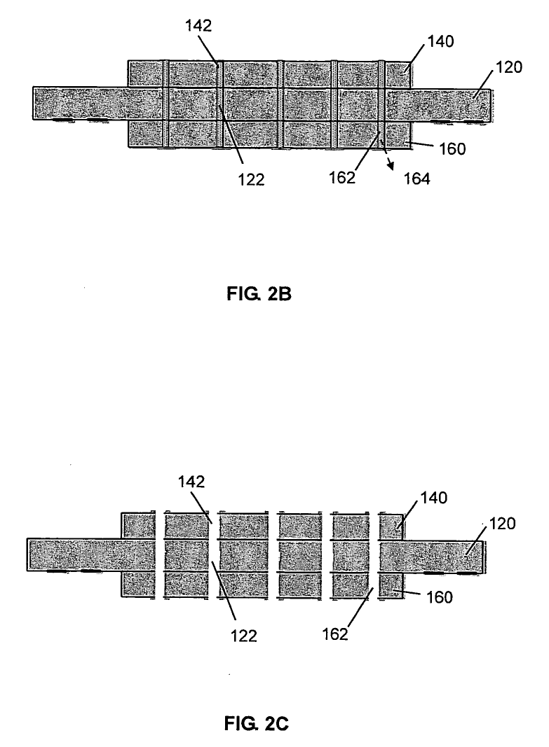

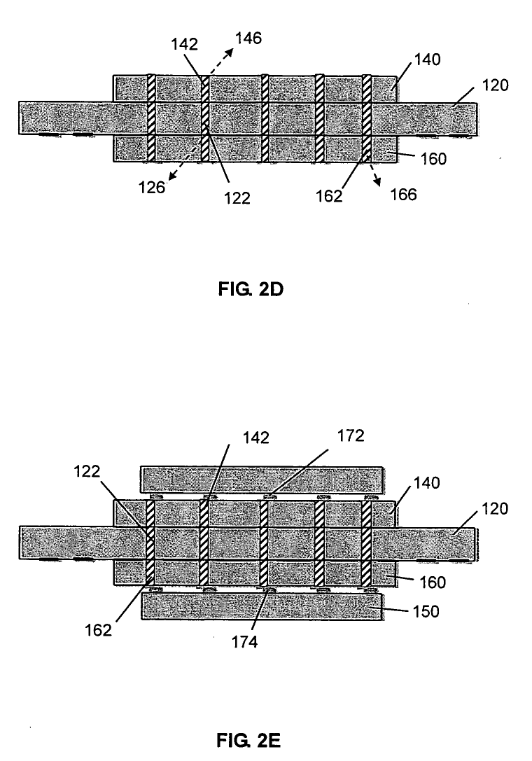

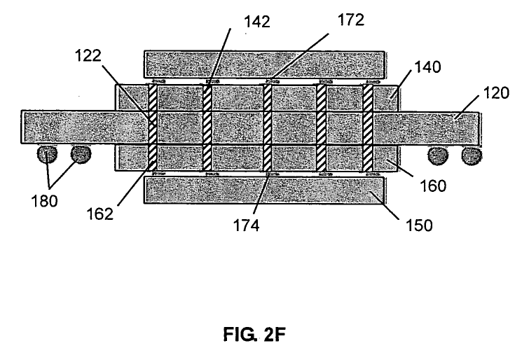

FIGS. 2A-2F illustrates an embodiment of a method that may manufacture the semiconductor package 100. Referring to FIG. 2A, in one embodiment, the substrate 120 may be provided to comprise a set of through holes 122. Each through hole 122 may be filled or deposited with sacrificial material 124. In another embodiment, the second die 140 may be provided with a set of through vias 142, in which sacrificial material 144 may be implanted or deposited. For example, examples of the sacrificial material 124 and/or 144 may comprise sacrificial polymer or volatile polymer, such as polycarbonate, or polynorbornene. In another embodiment, the substrate 120 may be provided with bond pads 182 on its lower surface; however, in some embodiments, other suitable interconnects may be provided on the substrate 120, such as bumps, or bond fingers, solder ball lands, or conductive paste. In another embodiment, the substrate 120 may comprise interconnects on its upper surface to couple to the mother board 110.

Any suitable methods may be used to prepare the through holes or vias, such as drilling, punching, puncturing, piercing, etching, or any other hole-making methods, or via laser. In another embodiment, a patterned model (not shown) may be applied to the substrate 120 and/or the die 140 that may be flowable or in liquid state to form the through holes or vias. In another embodiment, the substrate 120 and/or the die 140 may be cured.

Referring to FIG. 2B, the second die 140 may be attached on one side of the substrate 120, e.g., the upper side of FIG. 2B. In one embodiment, the through vias 142 may each be aligned with a through hole 122. In another embodiment, the fourth die 160 may be attached on the other side of substrate 120, e.g., the lower side as shown in FIG. 2B. The fourth die 160 may also be provided with a set of through vias 162. Each through via 162 may be aligned with a through hole 122 and/or a through via 142. In one embodiment, sacrificial material 164 may be implanted in each through via 162. The sacrificial material 162 may be the same as the sacrificial materials 124 and/or 144. In another embodiment, die attachment material (not shown) may be utilized to secure the dies 140 and 160 on the substrate 120, including wafer level lamination film, dry film, and/or other suitable die attachment adhesive such as epoxy.

Referring to FIG. 2C, the sacrificial materials 124, 144 and 164 may be removed. In one embodiment, thermal decomposition may be utilized to remove the sacrificial materials 124, 142 or 164. For example, the sacrificial materials 124, 144 or 164 may be decomposed or volatilized after being kept at a temperature (e.g., about 100-200° C.) for a period of time, e.g., several minutes. In one embodiment, one example of the thermal decomposition may comprise curing, or backing. In another embodiment, a surface treatment such as plasma treatment may be utilized to remove any residue of the sacrificial materials 124, 144 or 164 and/or the die attachment material (not shown) in the through holes 122 and/or the through vias 142 and 162.

Referring to FIG. 2D, a set of interconnects may be formed to couple the dies 140 and 160 to the substrate 120. For example, conductive material or paste 126 may be plated into the through holes 122 and the conductive material 126 may be cured to form PTHs 122. Further, conductive material 146 and 166 may also be respectively deposited in the through vias 142 and 162 and cured to form plated through vias 142 and 162, respectively. In one embodiment, the conductive material 126 in each through hole 122 may contact the conductive material 146 in a corresponding through via 142 and the conductive material 166 in a corresponding through via 162. In one embodiment, the substrate 120 may be coupled to the dies 140 and 160 by the aligned PTHs 122 and plated through holes 142 and 162. In yet another embodiment, the conductive material 126, 146 and 166 may comprise the same composite. In another embodiment, examples of the conductive materials 122, 142 and 162 may comprise copper (e.g., copper paste, nano-copper paste), silver, tin, or any other conductive adhesive or composite.

As shown in FIG. 2E, the first die 130 may be attach to the second die 140 provided on the upper side of the substrate 120. The third die 150 may be attached to the fourth die 160 on the lower side of the substrate 120. The first die 130 may be coupled to the second die 140 by a set of bumps 172 provided between the two dies. In one embodiment, the bumps 172 may secure the first die 130 to the second die 140. In another embodiment, a bump 172 may be coupled to a plated through via 142. Similarly, the third die 150 may be coupled to the fourth die 160 by a set of bumps 174 provided between the two dies.

Referring to FIG. 2F, a set of solder balls 180 may be attached to the lower side of the substrate 120 that may comprise a set of corresponding ball lands or pads (not shown). In another embodiment, referring to FIG. 1, the set of solder balls 180 may be further attached to the mother board 110 to couple the substrate 120 to the mother board 110. The mother board 110 may be configured with a set of ball lands or pads (not shown) that each may connect a solder ball 180. Referring to FIG. 1, in one embodiment, the opening 112 may be formed in the mother board 110 to accommodate the package 100, e.g., the one or more dies on a lower side of the substrate 120. In another embodiment, the solder balls 180 may not disposed in the opening 112. While FIG. 2F illustrates using solder balls 180 to couple the substrate 120 to the mother board 110, in some embodiments, any other interconnects may be utilized, such as wire bonds, bond pads, bumps, conductive protrusions, pins, or other suitable interconnects.

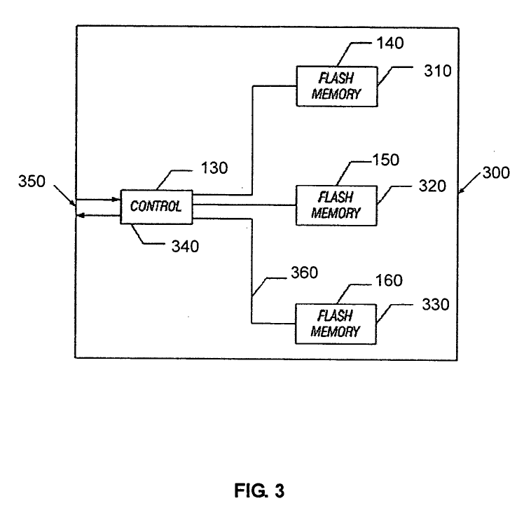

FIG. 3 illustrates an embodiment of a memory system 300. In one embodiment, the memory system 300 may utilize the package as shown in FIG. 1. In one embodiment, a universal serial bus (USB) flash memory system or any other memory system may be formed. In one embodiment, the memory system 300 may comprise a control 340 that may be implemented as the first die 130 on the substrate 120. For example, the control 340 may comprise a memory controller, a digital signal processor (DSP), a processor, logic circuit or any other control unit or device. The memory system 300 may comprise one or more flash memories, such as flash memories 310, 320, and 330 that may be coupled to the control 340. In one embodiment, the flash memory 310 may be implemented by the second die 140, the flash memory 320 may be implemented by the third die 150, the flash memory 330 may be implemented by the fourth die 160.

One or more interconnects 360 may couple the control 340 to the flash memories 310, 320 and 330. The interconnects 360 may comprise the substrate 120, as well as the interconnects in the package 100 such as PTHs 122, plated through vias 142, 162, bumps 172, 174, and/or the solder balls 180. In one embodiment, the memory system 300 may be coupled to an external I/O 350 via the substrate 120 and the solder balls 180. Although the embodiment of FIG. 3 is illustrated to use three flash memories, in some embodiments, other memory devices may be utilized, such as NOR, NAND, dynamic random access memory (DRAM). In another embodiment, memory devices 310, 320 and 330 may be the same type; however, in some embodiments, the memory devices may be different types. Again, in some embodiments, a different number of memory devices may be utilized. Furthermore, while FIG. 3 is illustrated to use die 130 as the control 340, in some embodiments, one or more other dies may be utilized. For example, referring to FIG. 1, in one embodiment, die 140 may be implemented as the control 340 and dies 130, 150 and 160 may be implemented as memory devices.

While the methods of FIGS. 2A-2F are illustrated to comprise a sequence of processes, the method in some embodiments may perform illustrated processes in a different order. Further, while the embodiments of FIG. 1 are illustrated to comprise a certain number of dies, pads, interconnects, PTHs, vias, and substrates, some embodiments may apply to a different number. In some embodiments, other numbers of dies, substrates, and arrangements may be used.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A semiconductor package, comprising:
a substrate comprising a first die on its upper side and a second die on its lower side,
a first interconnect provided in the substrate, wherein the first interconnect is to reach the upper side and the lower side to couple the first die and the second die to the substrate.

2. The semiconductor package of claim 1, wherein the first interconnect penetrates through the substrate.

3. The semiconductor package of claim 1, wherein the first interconnect comprises a plated through hole.

4. The semiconductor package of claim 1, comprising:
an upper die provided on the first die, and
an upper interconnect provided in the first die, wherein the second interconnect is coupled to the first interconnect to couple the upper die to the substrate.

5. The semiconductor package of claim 1, comprising:
an upper die attached to the first die, wherein the upper die is coupled to the substrate by a plated through via that is coupled to the first interconnect.

6. The semiconductor package of claim 1, comprising:
a lower die attached to the second die, and
a lower interconnect provided in the second die, wherein the lower interconnect is aligned with the first interconnect to couple the lower die to the substrate.

7. The semiconductor package of claim 3, comprising:
a lower die attached to the first die, wherein the lower die is coupled to the substrate by a plated through via that is aligned with the plated through hole.

8. The semiconductor package of claim 1, wherein the substrate is coupled to a mother board that comprises an opening to accommodate the second die.

9. The semiconductor package of claim 1, wherein the substrate is supported by a mother board that comprises an opening for the second die.

10. The semiconductor package of claim 4, wherein the upper die is coupled to the first die by a bump.

11. A method, comprising:
providing a substrate having a first die on its upper side and a second die on its lower side,
providing a first interconnect in the substrate, wherein the first interconnect penetrates through the substrate to couple the dies to the substrate.

12. The method of claim 11, wherein providing the first interconnect comprises:
providing a through hole for the first interconnect, wherein a sacrificial material is deposited in the through hole, and
removing the sacrificial material to fill a conductive material in the through hole.

13. The method of claim 11, comprising:
providing a second interconnect in the first die, wherein the second interconnect penetrates through the first die to couple to the first interconnect, and
providing a third interconnect in the second die, wherein the third interconnect penetrates through the second die to coupled to the first interconnect.

14. The method of claim 11, comprising:
providing a through via in each of the first die and second die, and
attaching the first die and the second die to the substrate, wherein the through vias are to align with a through hole for the first interconnect.

15. The method of claim 14, comprising:
providing a sacrificial material in each of the through vias and the through hole.

16. The method of claim 15, comprising:
removing the sacrificial material in each through via and the through hole, and
providing a conductive material in each through via and the through hole.

17. The method of claim 16, wherein removing the sacrificial material comprises curing the sacrificial material to decompose the sacrificial material.

18. The method of claim 15, wherein the sacrificial material comprises sacrificial polymer or volatile polymer.

19. The method of claim 11, comprising:
providing an outer die on each of the first die and the second die,
providing a plated through via in both the first die and the second die, wherein the plated through vias are coupled to the first interconnect to couple the outer dies to the substrate.

20. The method of claim 11, comprising:
attaching the substrate to a mother board, wherein the mother board comprises an opening wherein the second die locates.

21. A memory system, comprising:
a substrate,
a set of memory devices, wherein each memory device is provided on the substrate, and
a first interconnect provided in the substrate, wherein the first interconnect is to reach an upper side and a lower side to couple the substrate and a memory device that is attached to each of the upper and lower sides.

22. The memory system of claim 21, comprising:
a control attached to the substrate, wherein the control comprises a plated through via connected with the first interconnect to couple the substrate with one of the set of memory devices that is attached to the control.

23. The memory system of claim 21, comprising:
a control attached to one of the set of memory devices, wherein the memory device comprises a plated through via coupled to the first interconnect to couple the control to the substrate.

24. The memory system of claim 21, wherein the first interconnect comprises a plated through hole.

25. The memory system of claim 21, wherein the memory devices comprise a set of dies.
